(19) United States
(12) Patent Application Publication
(10) Pub. No.: US 2018/0226442 A1
(43) Pub. Date: Aug. 9, 2018

(54) IMAGE SENSOR AND MANUFACTURING METHOD THEREOF

(71) Applicant: Powertech Technology Inc., Hsinchu County (TW)

(72) Inventor: Kun-Yung Huang, Hsinchu County (TW)

(73) Assignee: Powertech Technology Inc., Hsinchu County (TW)

(21) Appl. No.: 15/427,055

(22) Filed: Feb. 8, 2017

(51) Int. Cl. H01L 27/146

(52) U.S. Cl. CPC H01L 27/14618; H01L 27/14683; H01L 27/14636

(57) ABSTRACT

An image sensor including a device chip, a plurality of spacers, a dam layer, a lid, and a plurality of conductive terminals. The device chip has a first surface and a second surface opposite to the first surface. The device chip includes a sensing area on the first surface and a plurality of conductive pads surrounding the sensing area. The spacers are over the first surface of the device chip. The dam layer encapsulates the conductive pads and the spacers. The lid is over the dam layer. The conductive terminals are over the second surface of the device chip and are electrically connected to the conductive pads. In addition, a manufacturing method of the image sensor is also provided.

### BACKGROUND OF THE INVENTION

### 1. Field of the Invention

The present invention generally relates to an image sensor and a manufacturing method thereof, and more particularly, to an image sensor having spacers formed within a dam layer.

### 2. Description of Related Art

In recent years, with the rapid progress of electronic technologies and the prosperous development of high-tech electronic industries, more user-friendly electronic products with better functions continuously emerge and evolve toward a light, thin, short and small trend.

For example, as the development of image sensor moving toward chip scale packages, material selection of a dam layer in the image sensor becomes crucial for better product reliability. Conventionally, a photosensitive material is adopted. However, such material usually possesses a high coefficient of thermal expansion (CTE) and a low Young's modulus, which would cause deformation of the electrodes during the manufacturing process of the image sensor. Alternatively, a multi-layered dam structure had been proposed. Nevertheless, the multi-layered dam structure adds complexity and cost to the manufacturing process of the image sensor. Therefore, development of the manufacturing process and material selection of the dam layer has become an important topic in the field.

### SUMMARY OF THE INVENTION

The present invention provides an image sensor and a manufacturing method thereof, which is able to alleviate the problem of electrode deformation while simplifying the manufacturing process of the image sensor. As such, the reliability of the image sensor may be sufficiently enhanced and the manufacturing cost of the image sensor may be sufficiently reduced.

The present invention provides an image sensor including a device chip, a plurality of spacers, a dam layer, a lid, and a plurality of conductive terminals. The device chip has a first surface and a second surface opposite to the first surface. The device chip includes a sensing area on the first surface and a plurality of conductive pads surrounding the sensing area. The spacers are over the first surface of the device chip. The dam layer encapsulates the conductive pads and the spacers. The lid is over the dam layer. The conductive terminals are over the second surface of the device chip and are electrically connected to the conductive pads.

The present invention provides a manufacturing method of an image sensor. The method includes at least the following steps. First, a device wafer is provided. The device wafer has a first surface and a second surface opposite to the first surface. The device wafer includes a plurality of sensing areas on the first surface and a plurality of conductive pads surrounding the sensing areas. A plurality of spacers are formed over the first surface of the device wafer. The spacers are located between the sensing area and the conductive pads. A dam layer is formed over the first surface of the device wafer through screen printing. The dam layer encapsulates the spacers and the conductive pads. A lid is formed over the dam layer. A plurality of conductive terminals are formed over the second surface of the device wafer. The conductive terminals are electrically connected to the conductive pads.

Based on the above, a plurality of spacers are formed within the dam layer. Therefore, extra support may be provided between the device chip/wafer and the lid. Moreover, since the dam layer may be formed through screen printing, a broader range of material selection may be adopted. For example, the dam layer is not limited to a photosensitive material and may be a single-layered structure. As a result, materials having low CTE and high Young's modulus may be utilized as the material of the dam layer to avoid electrode deformation during manufacturing process of the image sensor. Therefore, the reliability of the image sensor may be enhanced. Furthermore, the manufacturing process may be simplified and the production cost may be reduced.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1M are schematic cross-sectional views illustrating manufacturing method of an image sensor according to an embodiment of the disclosure.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

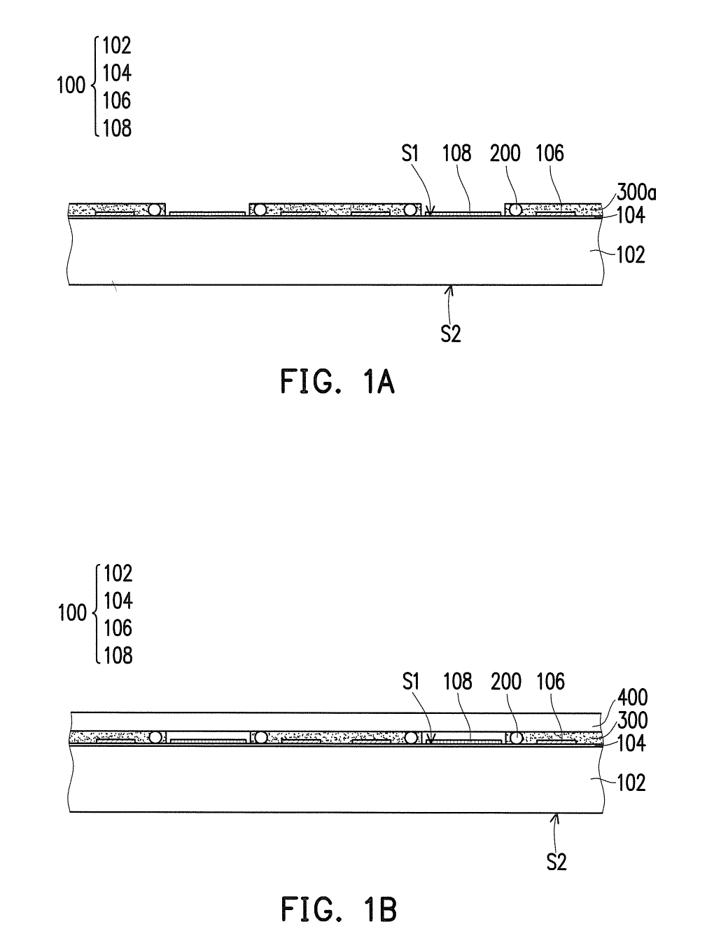

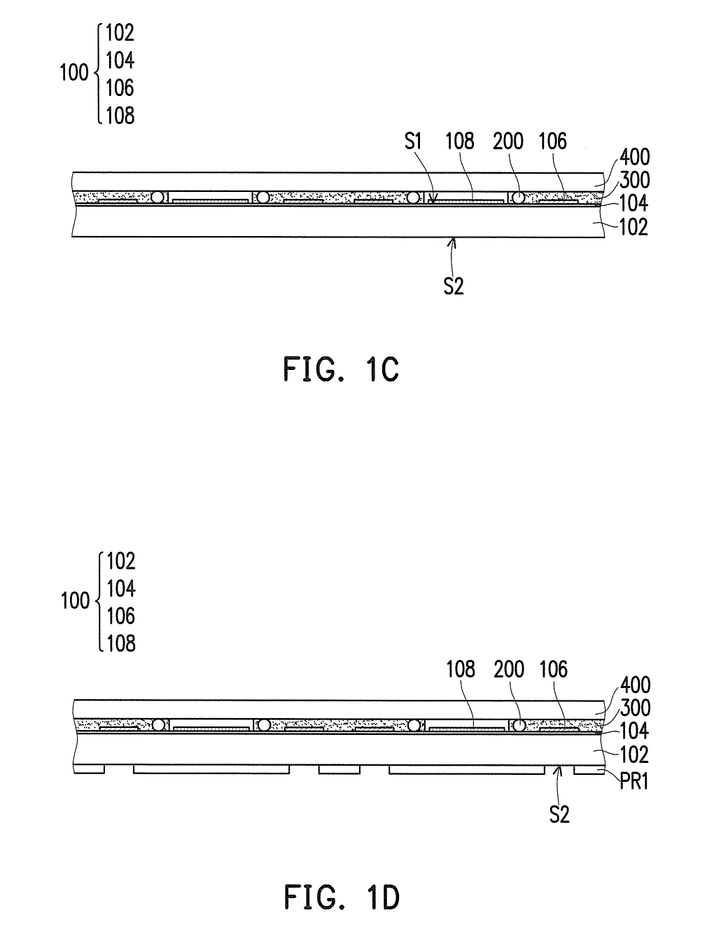

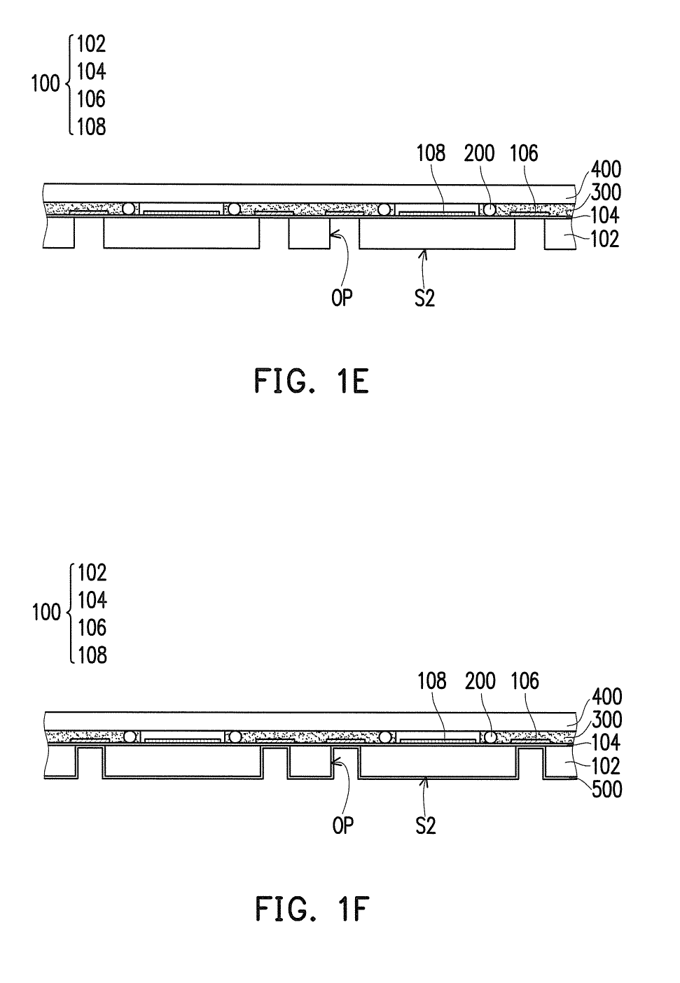

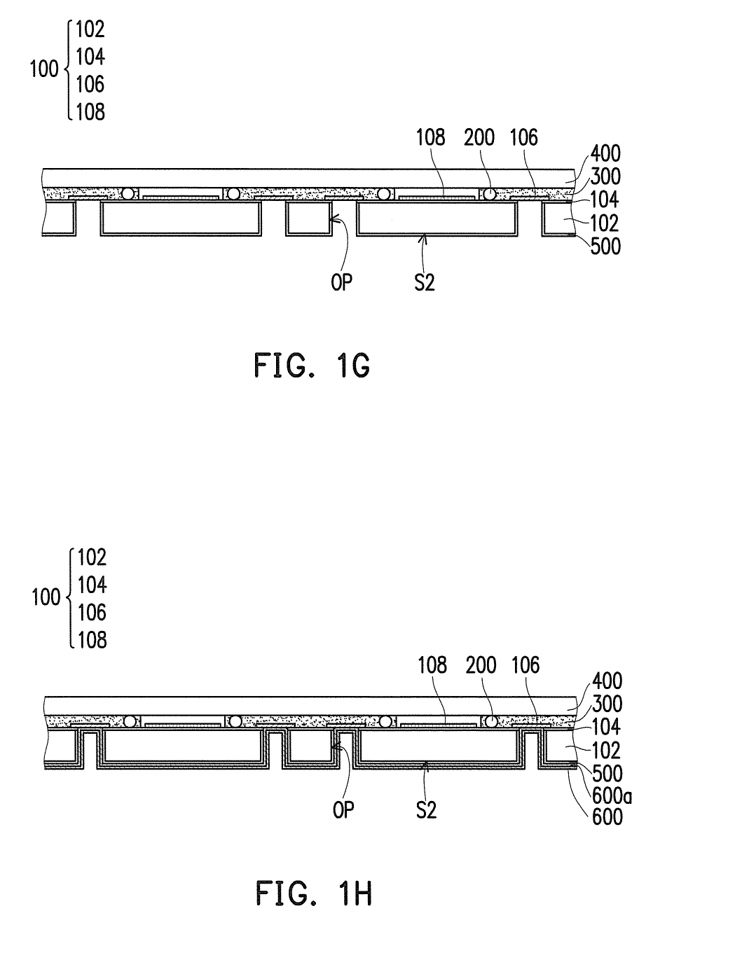

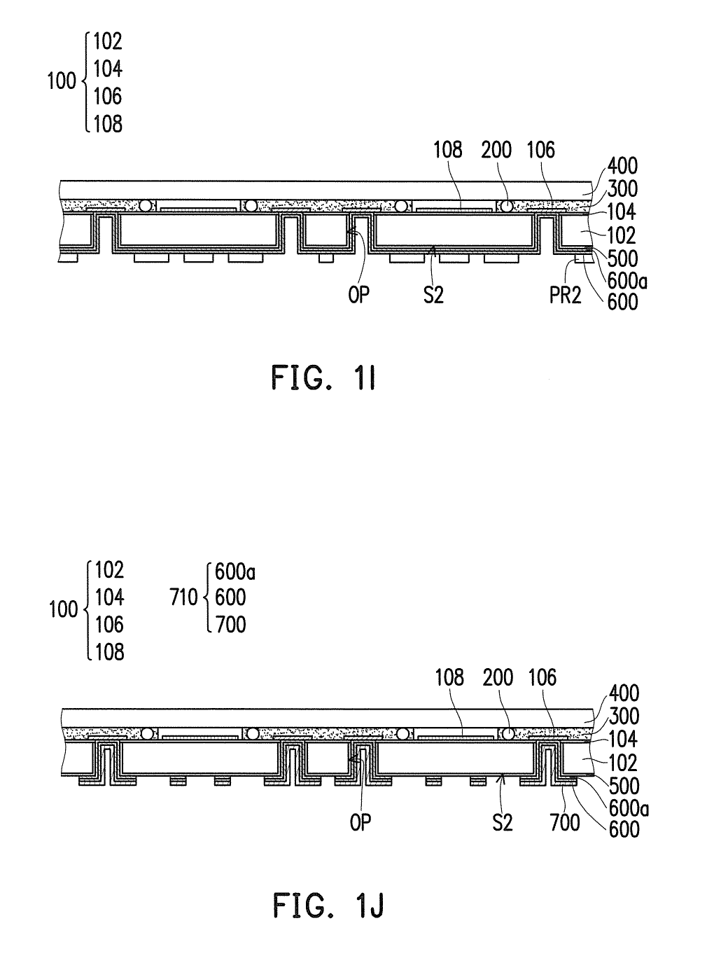

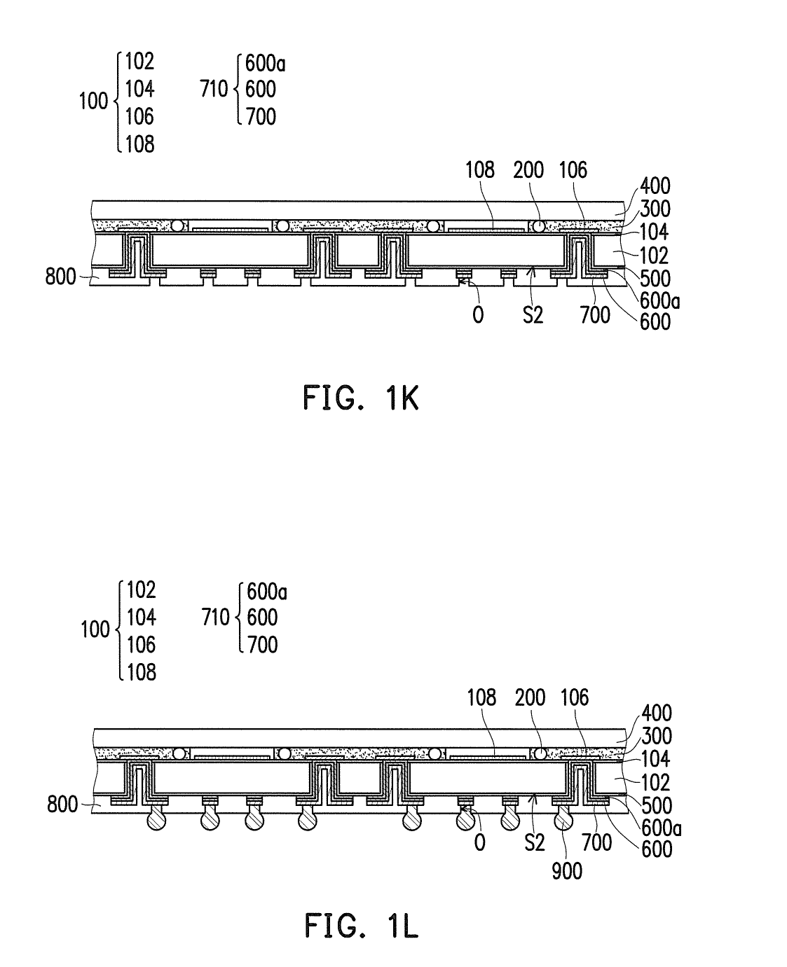

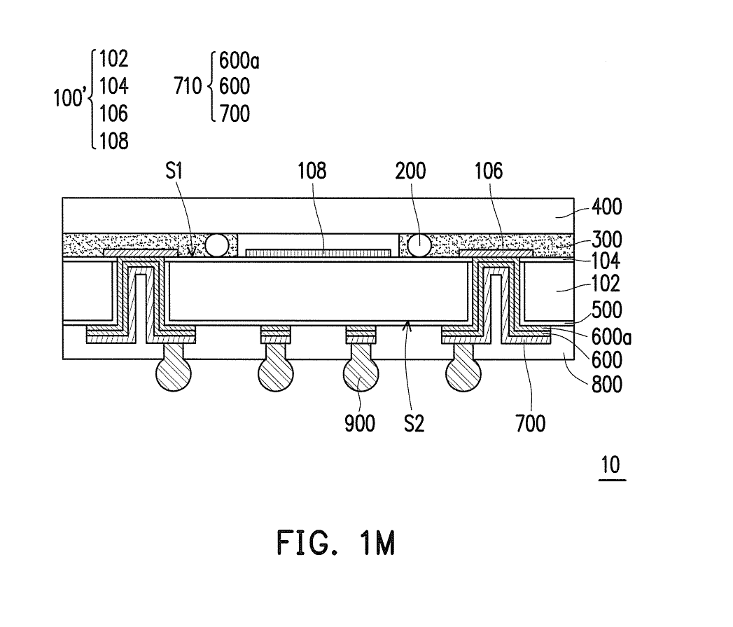

FIG. 1A to FIG. 1M are schematic cross-sectional views illustrating manufacturing method of an image sensor 10 according to an embodiment of the disclosure.

Referring to FIG. 1A, a device wafer 100 is provided. The device wafer 100 has a first surface S1 and a second surface S2 opposite to the first surface S1. The device wafer 100 includes a substrate 102, a dielectric layer 104, a plurality of conductive pads 106, and a plurality of sensing areas 108. The substrate 102 may be a semiconductor substrate. For example, the substrate 102 includes silicon. A plurality of active devices may be formed on or embedded in the substrate 102. In some embodiments, the active devices may include charge coupled devices (CCD), Complementary Metal-Oxide-Semiconductor (CMOS) transistors, or photodiodes. For example, when the active devices are CMOS transistors, the device wafer 100 is referred as a CMOS image sensor wafer. The dielectric layer 104 is disposed on the substrate 102 to constitute the first surface S1 of the device wafer 100. In some embodiments, the dielectric layer 104 may be an oxide layer. For example, the dielectric layer 104 may be formed by chemical vapor deposition (CVD) or performing thermal oxidation on the silicon substrate 102, so the dielectric layer 104 includes silicon dioxide.

The conductive pads 106 and the sensing areas 108 are located on the first surface S1, so the first surface S1 may be referred as an active surface of the device wafer 100. The sensing areas 108 are able to detect optical signals (for example, light) or image data transmitted from outside of the device. In some embodiments, the sensing areas 108 may include a color filer array formed by red color filters, green color filter, and blue color filters. The conductive pads 106 surround the sensing areas 108. In some embodiments, the conductive pads 106 are electrodes to allow voltages (power and/or ground) to be transmitted to the active devices in the substrate 102 and the image sensing area 108. In some embodiments, the conductive pads 106 are made of aluminium. However, it construes no limitation in the present invention. In some alternative embodiments, other metallic materials such as copper, gold, tin, or silver may also be used to manufacture the conductive pads 106.

A plurality of spacers 200 are formed over the first surface S1 of the device wafer 100. The spacers 200 are located between the conductive pads 106 and the sensing areas 108. The spacers 200 serve the function of providing sufficient gap between the device wafer 100 and the subsequently formed elements. In some embodiments, the spacers 200 also provide extra support to enhance the rigidity of the device as a whole. In some embodiments, a material of the spacers 200 may include metal, ceramic, plastic, or a combination thereof However, other materials with suitable rigidity may also be utilized as the spacers 200. Each spacer 200 has a diameter ranges from 5 μm to 100 μm.

A dam material layer 300a is formed over the first surface S1. The dam material layer 300a is formed on the spacers 200 and the conductive pads 106 to encapsulate the spacers 200 and the conductive pads 106. In some embodiments, the dam material layer 300a may be formed by a screen printing process. For example, a stencil having a plurality of openings may be provided over the device wafer 100 and the spacers 200. The openings of the stencil expose the conductive pads 106 and the spacers 200 while covering the sensing areas 108. Subsequently, the dam material layer 300a is applied into the openings of the stencil. In other words, the dam material layer 300a is applied over the first surface S1 of the device wafer 100 such that the dam material layer 300a covers the conductive pads 106 and the spacers 200. On the other hand, the dam material layer 300a is not applied over the sensing areas 108. Thereafter, the stencil is removed.

Referring to FIG. 1B, a lid 400 is bonded to the dam material layer 300a and the dam material layer 300a is cured to form a dam layer 300. Since the dam material layer 300a has adhesive property, the lid 400 may be adhered to the dam material layer 300a before the curing process. The curing process may be performed through thermal curing or UV curing depending on the material selection of the dam material layer 300a. Since the dam layer 300 is formed by screen printing, the dam layer 300 is not required to be made of photosensitive material. For example, the dam layer 300 may include epoxy, acrylic, silicone, siloxane, polyimide, benzocyclobutene (BCB), or a combination thereof In some embodiments, the dam layer 300 is a single-layered structure. Moreover, in some embodiments, the dam layer 300 may include a plurality of fillers (not illustrated) dispersed therein. Each filler has a diameter less than the diameter of each spacer 200. In some embodiments, the dam layer 300 surround the sensing areas 108 so the dam layer 300 exhibits an O-ring structure from a top view.

The lid 400 is made of transparent material such that the optical signal from outside of the device may transmit through the lid 400 to reach the sensing areas 108. In some embodiments, the lid 400 includes optical glass. A hermetic space is formed between the lid 400 and the device wafer 100 by the dam layer 300.

Referring to FIG. 1C, a thickness of the substrate 102 of the device wafer 100 is reduced. In some embodiments, the second surface S2 of the device wafer 100 is grinded to reduce an overall thickness of the device wafer 100. The grinding process may be performed by techniques such as mechanical polishing, chemical mechanical polishing (CMP), or etching.

Referring to FIG. 1D, a photolithography process is performed. A patterned photoresist layer PR1 is formed over the grinded second surface S2 of the device wafer 100. The patterned photoresist layer PR1 includes, for example, photosensitive resin or other photosensitive materials. The patterned photoresist layer PR1 may be formed by first coating a photoresist material layer (not illustrated) onto the second surface S2 of the device wafer. Subsequently, with the aid of a mask (not illustrated), an exposure process and a development process is performed on the photoresist material layer to render the patterned photoresist layer PR1. The openings formed by the patterned photoresist layer PR1 correspond to the location of the conductive pads 106. In some embodiments, an After Development Inspection (ADI) process may be performed on the patterned photoresist layer PR1 to ensure the precision of the location of the openings.

Referring to FIG. 1E, an etching process is performed to form a plurality of through holes OP penetrating through the substrate 102. The etching process may include wet etching or dry etching. In some embodiments, the dielectric layer 104 may serve as an etch stop layer. In other words, after the etching process, the conductive pads 106 are still well protected by the dielectric layer 104. Thereafter, the patterned photoresist layer PR1 is removed.

Referring to FIG. 1F, an oxide layer 500 is formed over the second surface S2 of the device wafer 100 and is filled into the through holes OP. The oxide layer 500 is formed in a conformal manner such that the oxide layer 500 extends into the through holes OP to cover sidewalls of the through holes OP. The oxide layer 500 may include low temperature oxide such as silicon dioxide. The oxide layer 500 may be formed through Plasma-enhanced chemical vapor deposition (PECVD), atmospheric pressure chemical vapor deposition (APCVD), or low pressure chemical vapor deposition (LPCVD).

Referring to FIG. 1G, portions of the dielectric layer 104 and portions of the oxide layer 500 exposed by the through holes OP are removed to expose bottom surfaces of the conductive pads 106. The dielectric layer 104 and the oxide layer 500 may be removed through dry etching.

Referring to FIG. 1H, an adhesive layer 600a and a seed layer 600 are consecutively sputtered over the oxide layer 500 and the bottom surfaces of the conductive pads 106. The adhesive layer 600a and the seed layer 600 extend into the through holes OP such that the adhesive layer 600a is directly in contact with the conductive pads 106. In some embodiments, other than enhancing the adhesion between the conductive pads 106 and the seed layer 600, the adhesive layer 600a also serves as a barrier layer. The adhesive layer 600a may include Ti or TiW and the seed layer may include copper or gold, for example.

Referring to FIG. 1I, a patterned photoresist layer PR2 is formed over the adhesive layer 600a and the seed layer 600. The formation method and the material of the patterned photoresist layer PR2 are similar to that of the patterned photoresist layer PR1 in FIG. 1D, so the detailed descriptions are omitted herein. The openings formed by the patterned photoresist layer PR2 expose at least part of the seed layer 600.

Referring to FIG. 1J, a conductive material layer 700 is filled into the openings formed by the photoresist layer PR2. In other words, the conductive material layer 700 is formed on the seed layer 600 exposed by the patterned photoresist layer PR2. The conductive material layer 700 extends into the through holes OP such that the conductive material layer 700 is directly in contact with the seed layer 600. The conductive material layer 700 includes, for example, a single-layered structure of copper or a multi-layered structure of copper/nickel/gold. Thereafter, the patterned photoresist layer PR2, the seed layer 600 exposed by the conductive material layer 700, and the adhesive layer 600a underneath the exposed seed layer 600 are removed, so as to formed a plurality of through silicon vias (TSV) 710. In other words, the TSVs 710 are formed by removing the patterned photoresist layer PR2 and the adhesive layer 600a and the seed layer 600 covered by the patterned photoresist layer PR2. As such, part of the adhesive layer 600a, part of the seed layer 600, and the conductive material layer 700 constitute the TSVs 710. The patterned photoresist layer PR2 may be removed through a stripping process and portions of the adhesive layer 600a and the seed layer 600 may be removed through an etching process.

Referring to FIG. 1K, a protection layer 800 is formed over the second surface S2 of the device wafer 100. In some embodiments, the protection layer 800 is disposed over the TSVs 710 and the oxide layer 500 to protect these layers. The protection layer 800 includes, for example, solder mask. However, the present invention is not limited thereto. Other materials having protection functions may also be utilized as the protection layer 800. The protection layer 800 may be formed through dry film lamination or liquid film coating. As illustrated in FIG. 1K, a plurality of openings O are formed in the protection layer 800 to expose at least part of the TSVs 710.

Referring to FIG. 1L, a plurality of conductive terminals 900 are formed over the protection layer 800. The conductive terminals 900 are electrically connected to the TSVs 710 through the openings O of the protection layer 800. In some embodiments, the conductive terminals 900 are conductive balls such as solder balls. However, it construes no limitation in the present invention. In some alternative embodiments, the conductive terminals 900 may also take the form of conductive pillars or conductive bumps. The conductive terminals 900 may be formed through a ball placement process and a reflow process. As mentioned above, since the TSVs 710 are electrically connected to the conductive pads 106, the conductive terminals 900 are electrically connect to the conductive pads 106 through the TSVs 710.

Referring to FIG. 1M, a singulation process is performed on the structure illustrated in FIG. 1L to obtain a plurality of image sensors 10. In some embodiments, the device wafer 100 may be diced through cutting with rotating blade or laser beam.

The image sensor 10 includes a device chip 100′, a plurality of spacers 200, a dam layer 300, a lid 400, an oxide layer 500, a plurality of TSVs 710, a protection layer 800, and a plurality of conductive terminals 900. The device chip 100′ has a first surface S1 and a second surface S2 opposite to the first surface S1. The device chip 100′ includes a substrate 102, a dielectric layer 104, a sensing area 108, and a plurality of conductive pads 106. The sensing area 108 is located on the first surface S1 of the device chip 100′ and the conductive pads 106 surround the sensing area 108. The spacers 200 are over the first surface S2 of the device chip 100′ and are located between the sensing area 108 and the conductive pads 106. The dam layer 300 is over the first surface S1 to encapsulate the spacers 200 and the conductive pads 106. The lid 400 is disposed on the dam layer 300. The TSVs 710 penetrate through the substrate 102 and the dielectric layer 104 of the device chip 100′ to electrically connect with the conductive pads 106. The oxide layer 500 is located between the TSVs 710 and the device chip 100′ and between the protection layer 800 and the device chip 100′. The protection layer 800 covers the TSVs 710 and the oxide layer 500 to protect these layers. The conductive terminals 900 are disposed on the protection layer 800 and are electrically connected to the conductive pads 106 through the TSVs 710.

Based on the foregoing, a plurality of spacers are formed within the dam layer. Therefore, extra support may be provided between the device chip/wafer and the lid. Moreover, since the dam layer may be formed through screen printing, a broader range of material selection may be adopted. For example, the dam layer is not limited to a photosensitive material and may be a single-layered structure. As a result, materials having low CTE and high Young's modulus may be utilized as the material of the dam layer to avoid electrode deformation during manufacturing process of the image sensor. Therefore, the reliability of the image sensor may be enhanced. Furthermore, the manufacturing process may be simplified and the production cost may be reduced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. An image sensor, comprising:
a device chip having a first surface and a second surface opposite to the first surface, wherein the device chip comprises a sensing area on the first surface and a plurality of conductive pads surrounding the sensing area;
a plurality of spacers over the first surface of the device chip;
a dam layer encapsulating the conductive pads and the spacers;
a lid over the dam layer; and
a plurality of conductive terminals over the second surface of the device chip, wherein the conductive terminals are electrically connected to the conductive pads.

2. The image sensor according to claim 1, further comprising a plurality of through silicon vias (TSV), the TSVs penetrate through a substrate of the device chip, and the conductive terminals are electrically connected to the conductive pads through the TSVs.

3. The image sensor according to claim 2, further comprising a protection layer over the second surface of the device chip.

4. The image sensor according to claim 3, further comprising an oxide layer located between the TSVs and the device chip and between the protection layer and the device chip.

5. The image sensor according to claim 1, wherein a diameter of each spacer ranges from 5 μm to 100 μm.

6. The image sensor according to claim 1, wherein the dam layer comprises a plurality of fillers and each filler has a diameter less than a diameter of each spacer.

7. The image sensor according to claim 1, wherein the dam layer is a single-layered structure.

8. The image sensor according to claim 1, where a material of the dam layer comprises epoxy, acrylic, silicone, siloxane, polyimide, benzocyclobutene (BCB), or a combination thereof.

9. The image sensor according to claim 1, wherein a material of the conductive pads comprises aluminium.

10. The image sensor according to claim 1, wherein a material of the spacers comprises metal, ceramic, plastic, or a combination thereof.

11. A manufacturing method of an image sensor, comprising:
providing a device wafer, wherein the device wafer has a first surface and a second surface opposite to the first surface, the device wafer comprises a plurality of sensing areas on the first surface and a plurality of conductive pads surrounding the sensing areas;
forming a plurality of spacers over the first surface of the device wafer, wherein the spacers are located between the sensing areas and the conductive pads;
forming a dam layer over the first surface of the device wafer through screen printing, wherein the dam layer encapsulates the spacers and the conductive pads;
forming a lid over the dam layer; and
forming a plurality of conductive terminals over the second surface of the device wafer, wherein the conductive terminals are electrically connected to the conductive pads.

12. The method according to claim 11, wherein the step of forming the dam layer comprises:
applying a dam material layer over the first surface of the device wafer through screen printing to encapsulate the spacers and the conductive pads;
curing the dam material layer to form the dam layer.

13. The method according to claim 11, further comprising:
forming a plurality of through holes corresponding to the conductive pads in the device wafer;
filling a conductive material layer into the through holes to form a plurality of through silicon vias (TSV), wherein the conductive terminals are electrically connected to the conductive pads through the TSVs.

14. The method according to claim 13, further comprising:
forming an oxide layer over the second surface of the device wafer and over sidewalls of the through holes.

15. The method according to claim 11, further comprising:
forming a protection layer over the second surface of the device wafer.

16. The method according to claim 11, further comprising:
dicing the device wafer, so as to form a plurality of image sensors.

17. The method according to claim 11, wherein a diameter of each spacer ranges from 5 μm to 100 μm.

18. The method according to claim 11, wherein the dam layer is a single-layered structure.

19. The method according to claim 11, wherein a material of the dam layer comprises epoxy, acrylic, silicone, siloxane, polyimide, benzocyclobutene (BCB), or a combination thereof.

20. The method according to claim 11, wherein a material of the spacers comprises metal, ceramic, plastic, or a combination thereof.
